(19) United States
(12) Patent Application Publication
(10) Pub. No.: US 2025/0038732 A1
(43) Pub. Date: Jan. 30, 2025

(54) SURFACE ACOUSTIC WAVE FILTER WITH MASS ADDITION FILM FORMING ON ELECTRODES

(71) Applicant: WISOL CO., LTD., Osan-si (KR)

(72) Inventors: Hun Yong LEE, Osan-si (KR); Hae Kwan OH, Osan-si (KR); Sung Hyun LEE, Osan-si (KR)

(21) Appl. No.: 18/778,995

(22) Filed: Jul. 21, 2024

(30) Foreign Application Priority Data
Jul. 25, 2023 (KR) 10-2023-0096983

(51) Int. Cl. H03H 9/02; H03H 9/145

(52) U.S. Cl. CPC H03H 9/02889; H03H 9/02992; H03H 9/14544

(57) ABSTRACT

The present invention provides a surface acoustic wave filter with a mass addition film formed on a plurality of electrodes. The surface acoustic wave filter includes a substrate on which a support substrate, an energy confinement layer, and a piezoelectric layer are sequentially stacked; first and second bus bars extended in a first direction on the substrate and spaced apart from each other in a second direction perpendicular to the first direction; a plurality of IDT electrodes alternately extended from the first and second bus bars in the second direction and spaced apart from each other in the first direction; and a mass addition film extended in the first direction to cover the top surface of the plurality of IDT electrodes and the top surface of the substrate exposed between the plurality of IDT electrodes. The thickness of the mass addition film on the top surface of the substrate and the thickness of the mass addition film on the top surface of the plurality of IDT electrodes are different from each other.

### BACKGROUND OF THE INVENTION

### Field of the Invention

The present invention relates to a surface acoustic wave filter with a mass addition film formed on a plurality of electrodes, more specifically, to a surface acoustic wave filter that can suppress unnecessary transverse modes and spurious and improve insertion loss by means of a mass addition film formed to cover a plurality of alternately arranged interdigital (IDT) electrodes.

### Background of the Related Art

A Surface Acoustic Wave (SAW) refers to a wave that propagates along the surface of an elastic solid, and the surface acoustic wave propagates with energy concentrated near the surface and corresponds to a mechanical wave. The surface acoustic wave device is an electromechanical device that utilizes interactions between the surface acoustic waves and conduction electrons, and uses surface acoustic waves transferred to the surface of a piezoelectric crystal. The surface acoustic wave device may have a very wide range of industrial applications including sensors, oscillators, filters, and the like, and may be miniaturized and lightweighted to have various advantages such as robustness, stability, sensitivity, low cost, real-time property, and the like.

Spurious may be generated due to unnecessary transverse modes of a SAW filter, and may adversely affect performance as insertion loss increases. In order to reduce the transverse modes, a method of reducing the traveling speed of surface acoustic waves by forming a piston at an end of each IDT electrode has been proposed.

Referring to FIGS. 1A and 1B, a structure in which a piston is formed to overlap alternately arranged IDT electrodes is shown. The SAW filter shown in FIG. 1A has a configuration in which a mass addition film 40 is formed under each IDT electrode 30, and the SAW filter shown in FIG. 1B has a configuration in which a mass addition film 40 is formed under the IDT electrodes 30 in a structure of integrating each mass addition film 40 shown in FIG. 1A not to be separated. In this way, the piston structure may be implemented in various forms in a SAW filter according to the prior art.

### SUMMARY OF THE INVENTION

Therefore, the present invention has been made in view of the above problems, and it is an object of the present invention to provide a SAW filter having excellent characteristics in terms of Q factor and K², while reducing transverse modes and spurious, by adding a mass addition film.

The technical problems of the present invention are not limited to the technical problems mentioned above, and unmentioned other technical problems will be clearly understood by those skilled in the art from the following description.

To accomplish the above object, according to one aspect of the present invention, there is provided a Surface Acoustic Wave (SAW) filter with a mass addition film formed on a plurality of electrodes, the SAW filter comprising: a substrate on which a support substrate, an energy confinement layer, and a piezoelectric layer are sequentially stacked; first and second bus bars extended in a first direction on the substrate and spaced apart from each other in a second direction perpendicular to the first direction; a plurality of IDT electrodes alternately extended from the first and second bus bars in the second direction and spaced apart from each other in the first direction; a gap formed in a space between an end of the IDT electrode extended from the first bus bar and the second bus bar, or between an end of the IDT electrode extended from the second bus bar and the first bus bar; and a mass addition film extended in the first direction to cover the top surface of the plurality of IDT electrodes, wherein when the width of the gap is G, the width in the first direction of a portion where the end of the IDT electrode is formed in the gap due to an alignment error is a, and the thickness of the mass addition film on the IDT electrode is t,

$$( a / G ) / {t}^{1 / 2} \leq 0.08$$

is satisfied.

In some embodiments of the present invention, the density of the mass addition film may be 5 g/cm³ or less.

In some embodiments of the present invention, the SAW filter may further comprise a first dummy electrode extended from the second bus bar to face the end of the IDT electrode extended from the first bus bar, and a second dummy electrode extended from the first bus bar to face the end of the IDT electrode extended from the second bus bar, wherein the gap may be formed in a space between one end of the IDT electrode extended from the first bus bar and the first dummy electrode and in a space between one end of the IDT electrode extended from the second bus bar and the second dummy electrode.

In some embodiments of the present invention, the mass addition film may be extended in the first direction to cover one ends of the plurality of IDT electrodes.

In some embodiments of the present invention, the plurality of IDT electrodes may include: a plurality of first IDT electrodes extended from the first bus bar in the second direction and spaced apart from each other in the first direction; and a plurality of second IDT electrodes extended from the second bus bar in the second direction, spaced apart from each other in the first direction, and arranged alternately together with the plurality of first IDT electrodes, wherein the mass addition film may include a first mass addition film covering one ends of the plurality of first IDTs, and a second mass addition film covering one ends of the plurality of second IDTs.

In some embodiments of the present invention, the mass addition film may include at least one among SiO₂, Ta₂O₅, and Al₂O₃.

In some embodiments of the present invention, the thickness of the mass addition film on the top surface of the plurality of IDT electrodes may be greater than the thickness of the mass addition film on the top surface of the substrate.

In some embodiments of the present invention, the thickness of the mass addition film on the top surface of the substrate may be 95% or less of the thickness of the mass addition film on the top surface of the plurality of IDT electrodes.

In some embodiments of the present invention, the mass addition film may be extended across the plurality of IDT electrodes in one body to completely fill the areas between the plurality of IDT electrodes.

To accomplish the above object, according to another aspect of the present invention, there is provided a surface acoustic wave filter with a mass addition film formed on a plurality of electrodes, the SAW filter comprising: a substrate; a plurality of IDT electrodes formed on the substrate and alternately extended from first and second bus bars facing each other; at least one reflector formed on the substrate to be adjacent to the plurality of IDT electrodes; and a mass addition film extended to cover the top surface of the plurality of IDT electrodes, the top surface of the substrate exposed between the plurality of IDT electrodes, and at least a portion of the reflector, wherein the thickness of the mass addition film on the top surface of the substrate and the thickness of the mass addition film on the top surface of the plurality of IDT electrodes are different from each other.

In some embodiments of the present invention, the mass addition film may cover at least a portion of the outermost electrode of the at least one reflector, and may be formed to have a top surface of a square or ellipse shape.

In some embodiments of the present invention, a portion of the mass addition film on the plurality of IDT electrodes and a portion of the mass addition film on the reflector may be spaced apart from each other.

Specific details of other embodiments are included in the detailed description and drawings.

As the surface acoustic wave filter with a mass addition film formed on a plurality of electrodes according to an embodiment of the present invention may suppress unnecessary transverse modes and spurious as a mass addition film is formed to cover one ends of a plurality of IDT electrodes, insertion loss can be reduced.

In addition, the surface acoustic wave filter of the present invention may prevent decrease of Q and K² values as a mass addition film is formed on the top, rather than on the bottom, of electrodes, and may also suppress increase of alignment difficulty and manufacturing costs as the mass addition film is formed in a line pattern integrated as one body, rather than in a dot pattern arranged only on the top of each electrode.

The effects of the present invention are not limited to the effects mentioned above, and unmentioned other effects will be clearly understood by those skilled in the art from the description of the claims.

### BRIEF DESCRIPTION OF THE DRAWINGS

FIGS. 1A to 1B are views for explaining a SAW filter including a piston structure according to the prior art.

FIG. 2 is a top view showing a surface acoustic wave filter with a mass addition film formed on a plurality of electrodes according to an embodiment of the present invention.

FIG. 3 is a cross-sectional view taken along line A-A′ of FIG. 2.

FIGS. 4 and 5 are cross-sectional views taken along lines B-B′ and C-C′ of FIG. 2, respectively.

FIGS. 6 and 7 are views for explaining the effect of a surface acoustic wave filter with a mass addition film formed on a plurality of electrodes according to an embodiment of the present invention.

FIG. 8 is a view for explaining the effect of the thickness ratio of the mass addition film in a SAW filter according to an embodiment of the present invention.

FIGS. 9 to 12 are views for explaining a surface acoustic wave filter according to various embodiments of the present invention.

FIGS. 13A and 13B are views for explaining the effect of a case where the mass addition film is formed misaligned when the mass addition film is formed on the top of the IDT electrodes and on the top of the piezoelectric body in a SAW filter according to an embodiment of the present invention.

FIG. 14 is a view showing a tolerance range of alignment error for the density of a mass addition film of which the spurious amplitude is less than 10 dB.

FIG. 15 is a graph showing the values (horizontal axis) of the width of the alignment error of the mass addition films normalized by A determined by the pitch of the first and second IDT electrodes, and the measured amplitude of the spurious modes that can be formed in a surface acoustic wave filter when the thickness of the mass addition films varies.

FIG. 16 shows a table for deriving a correlation using the values of the width of the alignment error of the mass addition films normalized by A determined by the pitch of the first and second IDT electrodes and the thicknesses of the mass addition films.

### DETAILED DESCRIPTION OF THE PREFERRED EMBODIMENT

The advantages and features of the present invention and the method for achieving them will become clear by referring to the embodiments described below in detail together with the accompanying drawings. However, the present invention is not limited to the embodiments disclosed below and will be implemented in various different forms. These embodiments are provided only to make the disclosure of the present invention complete and to fully inform those skilled in the art of the present invention of the scope of the present invention, and the present invention is defined by the scope of the claims. Like reference numerals refer to like elements throughout the specification.

When one component is referred to as being “connected to” or “coupled to” another component, it includes both the cases of being directly connected or coupled to another components and cases of interposing other components in between. On the contrary, when one component is referred to as being “directly connected to” or “directly coupled to” another component, it indicates that no other component is intervening therebetween. “And/or” includes each of the mentioned items and all combinations of one or more of the items.

The terms used in this specification are to describe the embodiments and are not to limit the present invention. In this specification, singular forms also include plural forms unless specifically stated otherwise in the context. The terms “comprises” and/or “comprising” used in this specification means that the mentioned components, steps, operations, and/or elements do not exclude the presence or addition of one or more other components, steps, operations and/or elements.

Although first, second, and the like are used to describe various components, these components are of course not limited by these terms. These terms are used only to distinguish one component from the others. Therefore, it goes without saying that a first component mentioned below may also be a second component within the technical spirit of the present invention.

Unless defined otherwise, all the terms (including technical and scientific terms) used in this specification may be used as meanings that can be commonly understood by those skilled in the art. In addition, terms defined in commonly used dictionaries are not interpreted ideally or excessively unless clearly and specifically defined.

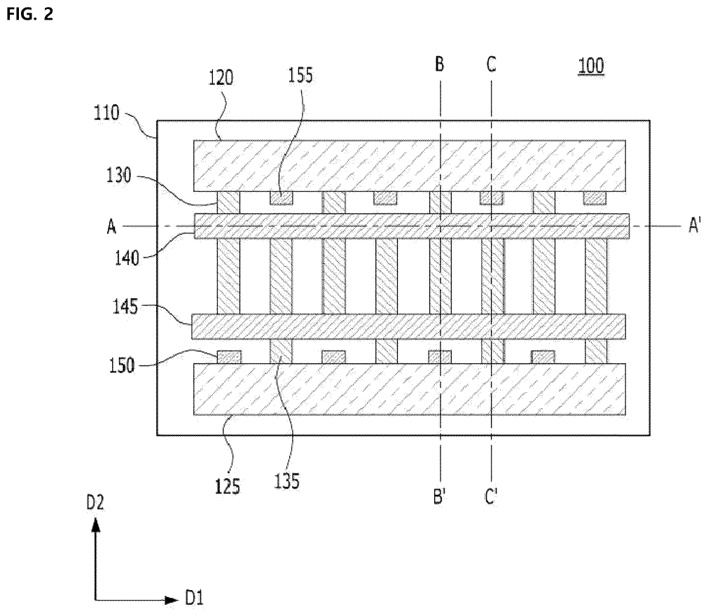

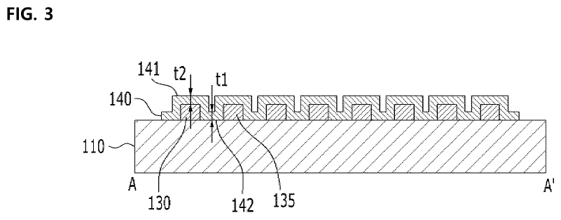

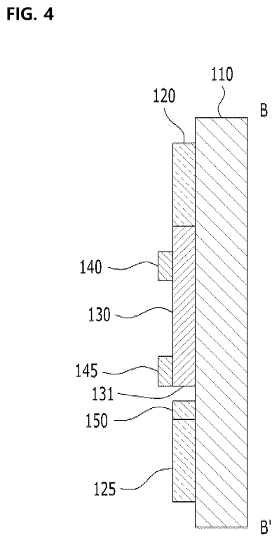

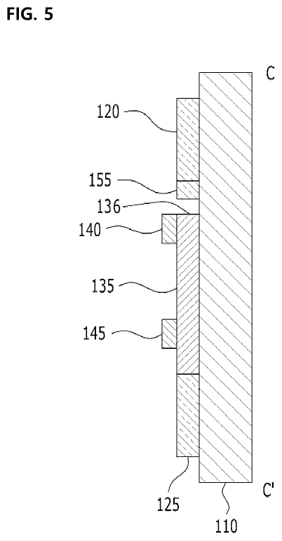

FIG. 2 is a view for explaining a SAW filter 100 with a mass addition film formed on a plurality of electrodes according to an embodiment of the present invention, and FIGS. 3 to 5 are cross-sectional views taken along lines A-A′, B-B′, and C-C′ of FIG. 2, respectively.

Referring to FIGS. 2 to 5, a SAW filter 100 with a mass addition film formed on a plurality of electrodes according to an embodiment of the present invention may include a substrate 110, a first bus bar 120, a second bus bar 125, a plurality of first IDT electrodes 130, a plurality of second IDT electrodes 135, a first mass addition film 140, and a second mass addition film 145.

The substrate 110 may be a multilayer substrate that may include a plurality of layers. Although the plurality of layers may include, for example, a support substrate containing silicon, a high sound speed film containing a material such as amorphous silicon a-Si or polysilicon, a low sound speed film containing silicon oxide SiO₂, and a piezoelectric film containing a material such as LiTaO₃ (LT) or LiNbO₃ (LN) located on the top of the low sound speed film, i.e., uppermost location, the present invention is not limited thereto, and the plurality of layers is omitted in the drawing and shown as a substrate 110.

The first bus bar 120 and the second bus bar 125 extended in the first direction D1 and spaced apart from each other in the second direction D2 may be disposed on the substrate 110.

The first bus bar 120 may be configured to include, for example, at least one or more materials selected among metals such as aluminum (Al) or an alloy film containing aluminum, copper (Cu), tungsten (W), molybdenum (Mo), gold (Au), silver (Ag), palladium (Pd), nickel (Ni), and the like, and metallic materials such as titanium (Ti), magnesium (Mg), zinc (Zn), cadmium (Cd), scandium (Sc), and ruthenium (Ru), and the like.

The second bus bar 125 may also include a conductive material similar to that of the first bus bar 120, and when the first bus bar 120 and the second bus bar 125 are formed through the same deposition process or the like, the first bus bar 120 and the second bus bar 125 may be configured to include the same material.

The plurality of first IDT electrodes 130 may be arranged to be extended from the first bus bar 120 in the second direction D2. In addition, the plurality of second IDT electrodes 135 may be arranged to be extended from the second bus bar 125 in the second direction D2.

The plurality of first and second IDT electrodes 130 and 135 may be spaced apart from each other in the first direction D1, and one first IDT electrode 130 and another IDT electrode 135 may be alternately arranged to be adjacent to each other.

The plurality of first and second IDT electrodes 130 and 135 may include a conductive material. The plurality of first IDT electrodes 130 may be formed to be integrated with the first bus bar 120, and the plurality of second IDT electrodes 135 may be formed to be integrated with the second bus bar 125. That is, each of the IDT electrodes 130 and 135 may be simultaneously formed through a process, e.g., a deposition process, the same as that of the bus bars 120 and 125, to which one end of the IDT electrode is connected.

The first mass addition film 140 may be extended in the first direction D1 to cross the plurality of first and second IDT electrodes 130 and 135. The first mass addition film 140 may be formed to cover the top surface of the plurality of first and second IDT electrodes 130 and 135 and the substrate 110 exposed between the plurality of first and second IDT electrodes 130 and 135. In addition, the first mass addition film 140 is formed to cover the top surface of one end 131 of the plurality of first IDT electrodes 130, and here, the one end 131 means the other end of one end of the first IDT electrode 130 connected to the first bus bar 120 as shown in the drawing.

The first mass addition film 140 may be formed in one body to be extended across the plurality of first and second IDT electrodes 130 and 135. That is, the first mass addition film 140 crosses the plurality of first and second IDT electrodes 130 and 135 and completely fills the areas between the plurality of electrodes to have a shape of one line pattern.

The first mass addition film 140 may include an insulator, and the thickness of the first mass addition film 140 needs to be decreased as the density increases to effectively suppress spurious.

In some embodiments of the present invention, the first mass addition film 140 is formed so that the deposition thickness on the substrate 110 is different from the deposition thickness on the first IDT electrode 130. Describing in more detail with reference to FIG. 3, the second thickness t2 of the first mass addition film 141 covering the top surface of the first IDT electrode 130 or the second IDT electrode 135 is greater than the first thickness t1 of the first mass addition film 142 covering the top surface of the substrate 110. That is, the first mass addition films 141 and 142 each having a different thickness may be formed according to the deposition position by adjusting the deposition rate through control of gas amount (e.g., flow rate), applied power, deposition atmosphere, and the like in the deposition process of forming the first mass addition film 140 while the substrate 110 and the first IDT electrode 130 have already been formed.

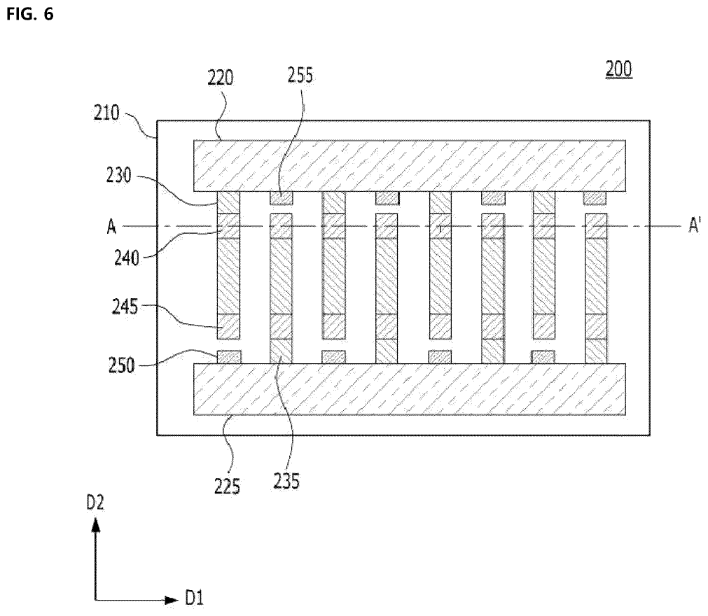

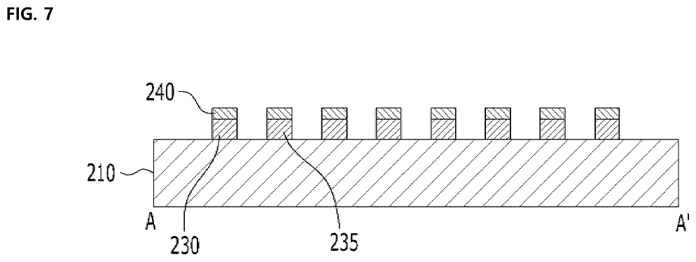

FIG. 6 is a top view showing a SAW filter according to another embodiment of the present invention, and FIG. 7 is a cross-sectional view showing the SAW filter of FIG. 6 taken along line A-A′.

Referring to FIG. 6, in a SAW filter 200 according to another embodiment of the present invention, a first mass addition film 240 may be formed to cover first and second IDT electrodes 230 and 235 and not to cover the top surface of the substrate 210 exposed between the plurality of first and second IDT electrodes 230 and 235. That is, the first mass addition film 240 may be formed in a dot shape on the first and second IDT electrodes 230 and 235 to be aligned in the first direction D1 and spaced apart from each other.

The second mass addition film 245 may also be formed to cover the first and second IDT electrodes 230 and 235 and not to cover the top surface of the substrate 210 exposed between the plurality of first and second IDT electrodes 230 and 235. At this point, the first mass addition film 240 and the second mass addition film 245 may be formed to be spaced apart from each other in the second direction D2, and the first mass addition film 240 and the second mass addition film 245 may be formed on one first IDT electrode 230 to be spaced apart from each other in the second direction D2. At this point, the second mass addition film 245 may be formed on an end, i.e., an edge portion, of the first IDT electrode 230, and the first mass addition film 240 may be formed on an edge portion of the second IDT electrode 235. Since the configuration of the first mass addition film 240 and the second mass addition film 245 is the same as that of the mass addition films 140 and 145 included in the SAW filter 100 described above with reference to FIGS. 2 to 6, other than that the first mass addition film 240 and the second mass addition film 245 do not cover the top surface of the substrate 210, detailed description thereof will be omitted.

As shown in FIG. 7, the first mass addition film 240 may be formed only on the first IDT electrode 230 or the second IDT electrode 235. At this point, although the side surface profile of the first mass addition film 240 may match the side surface profile of the first or second IDT electrode 230 or 235, the present invention is not limited thereto.

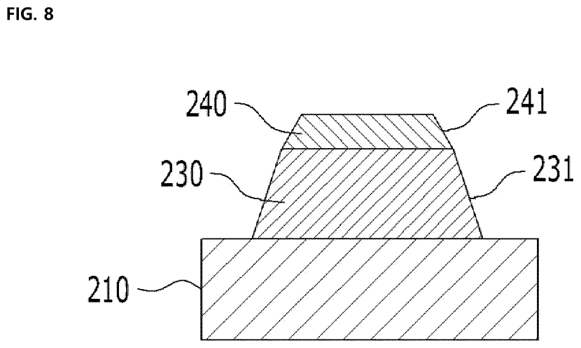

More specifically, referring to FIG. 8, the first IDT electrode 230 and the first mass addition film 240 may have a shape of tapered side surface while passing through an etching process when they are formed. That is, the cross-sectional shape of both the first IDT electrode 230 and the first mass addition film 240 is a shape close to a trapezoid having a width narrowed toward the top surface. At this point, the first IDT electrode 230 and the first mass addition film 240 may be formed so that the width of the bottom surface of the first mass addition film 240 matches the width of the top surface of the first IDT electrode 230. Meanwhile, although they may be formed so that one end of the top surface of the first IDT electrode 230 matches one end of the bottom surface of the first mass addition film 240, as shown in FIG. 8, the side surface profile of the first IDT electrode 230 and the side surface profile of the first mass addition film 240 may not match each other.

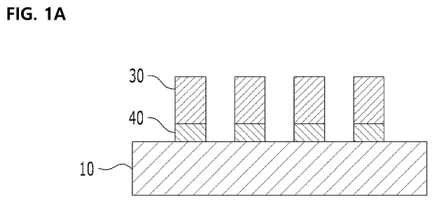

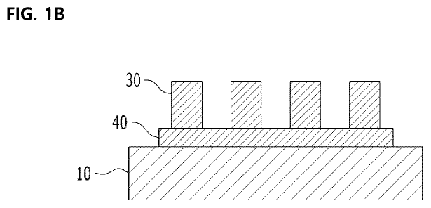

For example, the angle formed between the side wall 231 and the bottom surface (top surface of the substrate 210) of the first IDT electrode and the angle formed between the side wall 241 and the bottom surface (top surface of the first IDT electrode 230) of the first mass addition film may be different from each other as shown in FIG. 8. However, the present invention is not limited thereto, and it is absolutely possible that the side walls of the first IDT electrode 230 and the first mass addition film 240 may be aligned on a straight line like one structure as the sidewall profiles of the first IDT electrode 230 and the first mass addition film 240 match each other according to the processing conditions of forming the first IDT electrode 230 and the first mass addition film 240. Meanwhile, the effects that can be obtained from the SAW filters 100 and 200 according to the embodiments of the present invention by setting the thickness conditions of the first mass addition film 140 as described above will be described in more detail with reference to FIGS. 1A to 1B and 9 to 10.

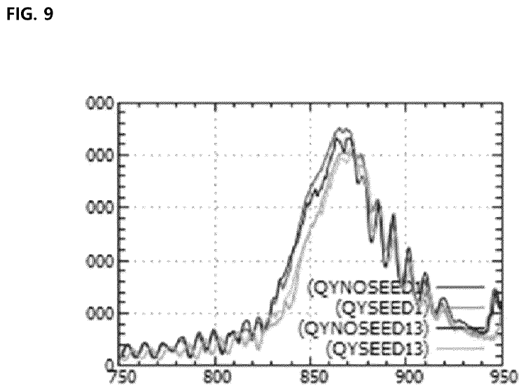

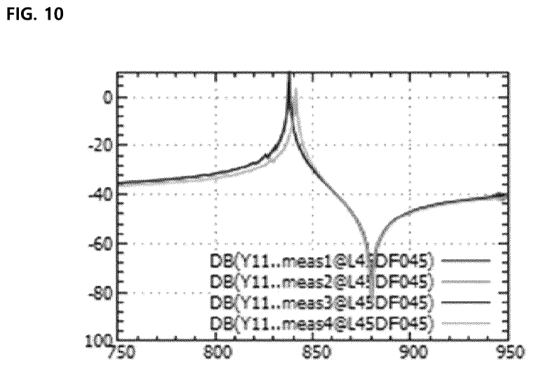

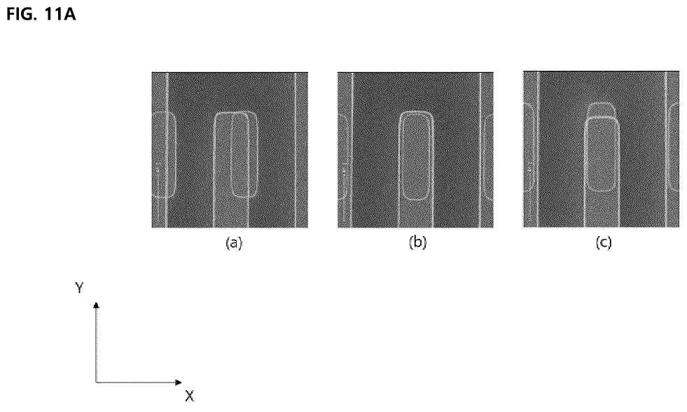

FIGS. 9 and 10 are views for explaining the effects of a SAW filter according to the position and shape of a mass addition film according to an embodiment of the present invention.

Referring to FIGS. 9 and 10, the graphs show Q factors (FIG. 9) and K² (FIG. 10) measured in a SAW filter having a piston structure of four cases. The red graph shows values of Q factor and K² measured in a structure of a mass addition film formed to cover both the plurality of IDT electrodes and the top surface of the substrate as described in an embodiment of the present invention, the green graph shows values of Q factor and K² measured in a structure of a mass addition film formed only under each of a plurality of IDT electrodes (FIG. 1A), the yellow graph shows values of Q factor and K² measured in a structure of a mass addition film formed as one body under a plurality of IDT electrodes (FIG. 1B), and the blue graph shows values of Q factor and K² measured in a structure of a mass addition film formed only on a plurality of IDT electrodes, not on the top surface of the substrate (FIG. 7).

First, as shown in FIGS. 1A and 1B, in a structure of a mass addition film formed under each of a plurality of IDT electrodes, it can be confirmed that filter performance is degraded due to decrease in the Q value and K² value. As the mass addition film is formed of an insulator such as SiO₂, SiN, Ta₂O₅, or Al₂O₃ for insulation of the plurality of IDT electrodes, the Q and K² values decrease compared to the case of directly connecting the IDT electrodes to the piezoelectric substrate. Particularly, decrease in the Q value is more noticeable in the yellow graph, i.e., in the structure in which the mass addition film 40 is formed in one body under the plurality of IDT electrodes 30 as shown in FIG. 1B.

Accordingly, it may be considered to form the mass addition film on the IDT electrodes in the structure of FIG. 7 not to cover the substrate, while preventing decrease in the Q and K² values. However, when the pattern of the mass addition film 240 is formed in a dot pattern as shown in FIG. 7, the pattern alignment difficulty may increase.

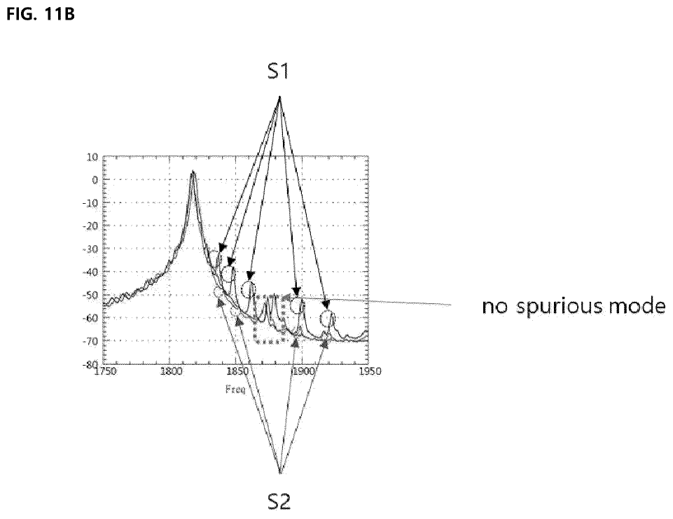

FIG. 11A is a view showing the pattern alignment error that may occur in the SAW filter shown in FIG. 7, and FIG. 11B is a view showing the change in the amplitude of a spurious due to the alignment error shown in FIG. 11A.

Referring to FIG. 11A, it shows an example of (a) a case where the mass addition film pattern is misaligned in a first direction X and (c) a case where the mass addition film pattern is misaligned in a second direction Y, with respect to a case where the mass addition film pattern is formed on the IDT electrodes to be aligned ((b) of FIG. 11A). The change in the amplitude of the spurious due to the alignment is shown in FIG. 11B, in which a graph (black) and spurious S1 due to the error of the first direction X and a graph (brown) and spurious S2 due to the error of the second direction Y are shown together with a graph (blue) of a case where the mass addition film pattern is aligned without an error.

As shown in the drawing, the amplitude of the spurious is affected by the alignment error of the first direction X or the second direction Y, and in particular, it can be known, from the amplitude of the spurious S1 generated by the alignment error of the first direction X, that the spurious are more sensitive to the alignment error of the first direction X.

Therefore, when it is desired to prevent the mass addition film 240 from generating an error of the first direction X on the IDT electrode 230, the mass addition film 240 should be formed to have a width smaller than the width of the IDT electrode 230, and in some cases, the pattern of the mass addition film 240 may be formed to be less than 80% of the width of the IDT electrode 230. For example, in the case of a SAW filter for 2 GHz, there may be a case where when the width of the IDT electrode is about 400 nm, the width of the mass addition film 240 is only 320 nm in maximum. In addition, considering the alignment tolerance or the like of a photo process, the width of the mass addition film is further decreased, and the thickness of the mass addition film required to obtain the same effect is further increased, and therefore, the process cost may be further increased.

Although the mass addition film may be formed to increase the width in the second direction Y of FIG. 11A, i.e., the longitudinal direction of the IDT electrode, this also has a limitation since the mass addition film should be formed within a range that does not interfere the central resonance region of the IDT electrode. Therefore, a method that can prevent increase in the process cost and suppress spurious most easily by setting a range of allowing alignment tolerance is needed.

Therefore, it is preferentially considered to form the SAW filter 100 according to an embodiment of the present invention so that the first mass addition film 140 covers the top surface of the substrate 110 exposed between adjacent IDT electrodes 130 and 135 connected to each other in a line pattern rather than a dot pattern, while covering the top surface of the plurality of first IDT electrodes 130.

At this point, decrease in the Q and K² values is minimized by forming the SAW filter 100 so that the second thickness t2 of the first mass addition film 141 covering the top surface of the first IDT electrodes 130 is greater than the first thickness t1 of the first mass addition film 142 covering the top surface of the substrate 110.

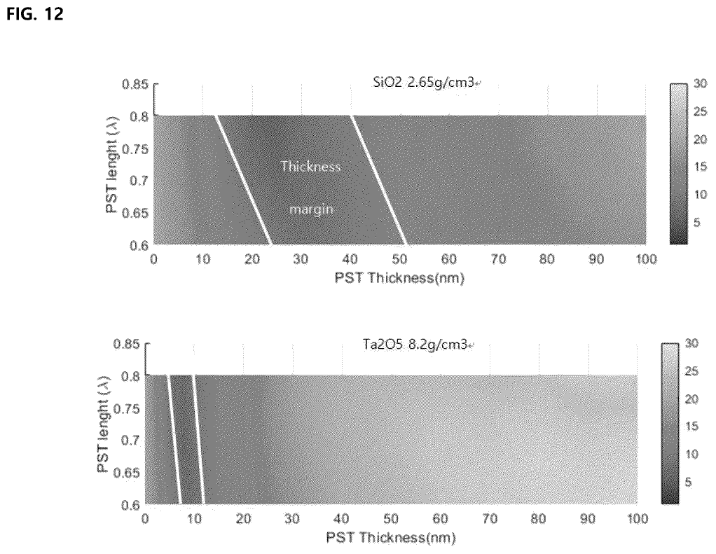

The thickness of the mass addition film is determined by the density of the mass addition film, and as the density of the mass addition film increases, the required thickness decreases. However, the higher the density of a material, the lower the thickness should be, but the change in the amplitude of spurious per 1 nm change of thickness is much more sensitive, and this is described with reference to FIG. 12.

FIG. 12 shows a result of experiment comparing the length when Ta₂SO₅ with a density of 8.2 g/cm3 is selected and the length when SiO₂ with a density of 2.69 g/cm3 is selected in the mass addition film of the SAW filter 100 according to an embodiment of the present invention.

Referring to FIG. 12, although the tolerance range of the thickness of the mass addition film for reducing the spurious amplitude to 10 dB or less is 25 nm or higher in the case of SiO₂ with a low density, the tolerance range of the thickness of the mass addition film for reducing the spurious amplitude to 10 dB or less is limited to the 5 nm level in the case of Ta₂O₆ with a high density. Since a material with a high density is more sensitive to spurious, it can be known that when a material with a low density is used for the mass addition film, it is more advantageous from the aspect of process control.

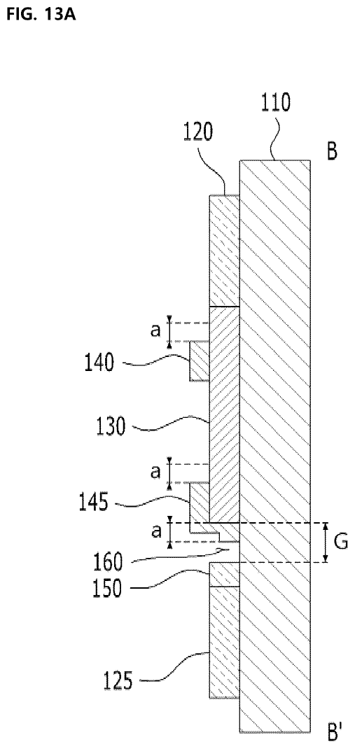

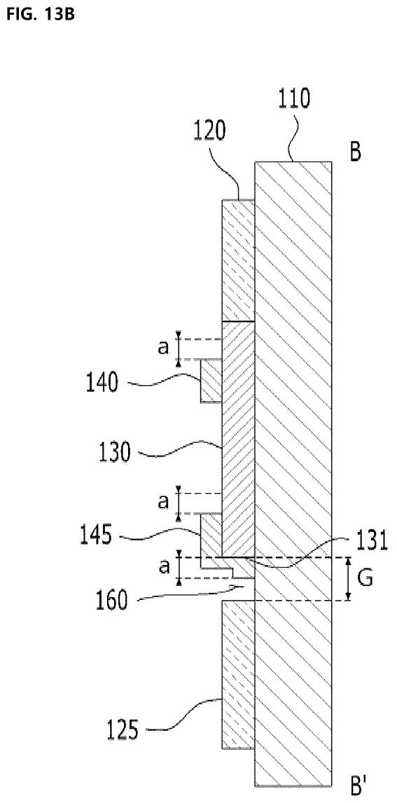

In the mass addition film, the degree of suppressing spurious amplitude is almost determined by the total mass. In the case of a material with a high density, the allowed range of thickness is small, and the tolerance range of misalignment is also small. This is described with reference to FIGS. 13A and 13B.

FIGS. 13A and 13B are views for explaining the effect of a case where the mass addition film is formed misaligned when the mass addition film is formed on the top of the IDT electrodes and on the top of the piezoelectric body in a SAW filter according to an embodiment of the present invention.

Referring to FIG. 13A, when the alignment error of the second mass addition film 145 is a, the second mass addition film 145 may be formed to invade the gap 160, which is the space between the one end 131 of the first IDT electrode 130 and a first dummy electrode 150, as much as a. Although not shown, the first mass addition film 140 may also be formed in the gap between the second IDT electrode 135 and a second dummy electrode 155 due to the alignment error. In addition, in another embodiment shown in FIG. 13B, when the first or second dummy electrode 150 or 155 is not formed, the gap 160 may include the space between one end 131 of the first IDT electrode 130 and the second bus bar 125.

When the first or second mass addition film 140 or 145 is formed in the gap 160 due to misalignment, the sound speed in the gap 160 decreases, so that the spurious suppression function is inevitably degraded. Therefore, it may be considered to form the first or second mass addition film 140 or 145 to be skewed in a direction getting away from the gap so that the first or second mass addition film 140 or 145 may not be formed in the gap.

For example, it is general that a surface acoustic wave device formed using lithography of KrF laser shows an alignment error of approximately 150 nm. This is considered in progressing the process in a way that one end of the first or second mass addition film 140 or 145 is spaced apart from the gap 160 as much as about 150 nm in maximum so that the first or second mass addition film 140 or 145 may not be formed in the gap 160. However, when the alignment error occurs in the inner direction of the first or second IDT electrode 130 or 135 rather than in the gap 160 direction, as the portions not covered by the mass addition film, including the end 131 or 136 of the first or second IDT electrode, increase, there is a problem in that the effect of suppressing the spuriousis lowered.

Since the surface acoustic wave filter according to an embodiment of the present invention has a spurious amplitude of less than 10 dB even when the first or second mass addition film 140 or 145 is formed to invade the gap 160, it does not need to form the first or second mass addition film 140 or 145 to be spaced apart from the gap 160 more than a predetermined distance considering the alignment tolerance level of the facility. Therefore, it may have a further improved spurious suppression function.

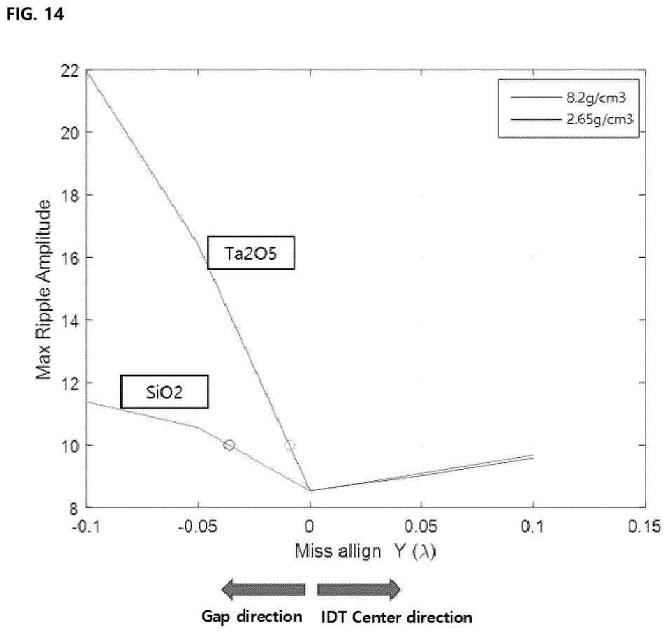

FIG. 14 is a view showing a tolerance range of alignment error for the density of a mass addition film of which the spurious amplitude is less than 10 dB.

Referring to FIG. 14, the horizontal axis represents the alignment error of the mass addition film, and the vertical axis represents the amplitude (dB) of spurious modes. At this point, the alignment error represents a number normalized by the wavelength λ determined by the pitch of the IDT electrode. A positive number means that the alignment error is in a direction getting away from the gap (toward the center of the IDT electrode), and a negative number means that the alignment error is in a direction approaching the gap. As shown in FIG. 14, it can be observed that as the density of a material of the mass addition film increases, the sensitivity due to the alignment error also increases.

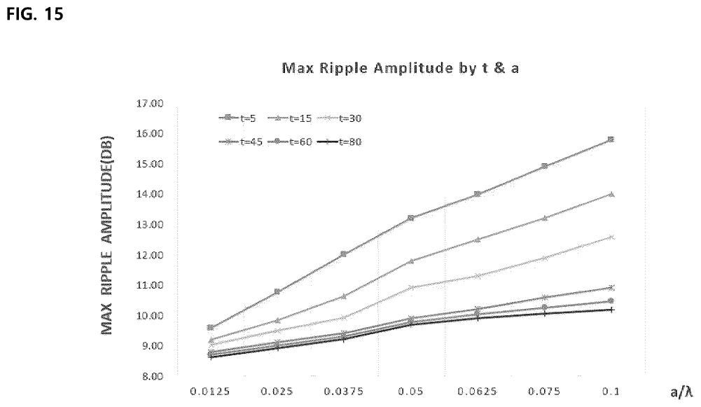

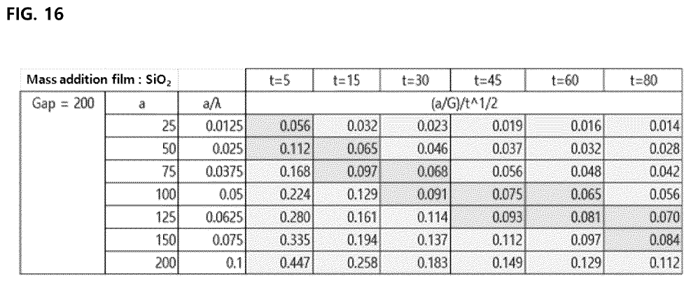

Meanwhile, the alignment error (a) of the mass addition film, the thickness of the mass addition film, and the width of the gap will be described with reference to FIGS. 15 and 16.

Referring to FIG. 15, it is a graph showing the values (horizontal axis) of the width (a) of the alignment error of the mass addition films 140 and 145 normalized by A determined by the pitch of the first and second IDT electrodes 130 and 135, and the measured amplitude of the spurious modes that can be formed in a surface acoustic wave filter when the thickness (t) of the mass addition films 140 and 145 varies. As described above, as the thickness (t) of the mass addition films 140 and 145 increases, the width of the alignment error normalized to suppress the amplitude of the spurious modes within 10 dB increases.

FIG. 16 shows a table for deriving a correlation using the values of the width (a) of the alignment error of the mass addition films 140 and 145 normalized by λ determined by the pitch of the first and second IDT electrodes 130 and 135, and the thicknesses (t) of the mass addition films 140 and 145, and this includes calculated values of (a/G)/t^{1/2}. The range for maintaining the spurious modes at 10 dB is highlighted, and in summary, the amplitude of the spurious modes that can be formed in a surface acoustic wave filter may be suppressed in less than 10 dB within a range of satisfying the correlation equation that expresses the thickness of the mass addition film defined by the correlation equation shown below and the degree of alignment error.

$$( a / G ) / {t}^{1 / 2} \leq 0.08$$

In some embodiments of the present invention, a plurality of first and second dummy electrodes 150 and 155 may be formed to be extended from the first bus bar 120 or the second bus bar 125. The first dummy electrode 150 may be extended from the second bus bar 125 in the second direction D2 to face one end 131 of the first IDT electrode 130, and the second dummy electrode 155 may be extended from the first bus bar 120 in the second direction D2 to face one end 136 of the second IDT electrode 135.

The first dummy electrode 150 may fill the gap between the one end 131 of the first IDT electrode 130 and the second bus bar 125 to suppress generation of unnecessary transverse modes. In the same way, the second dummy electrode 155 may also be located between the one end 136 of the second IDT electrode 135 and the first bus bar 120 to suppress generation of unnecessary transverse modes and reduce insertion loss.

Although the embodiments of the present invention have been described above with reference to the accompanying drawings, those skilled in the art may understand that the present invention can be implemented in other specific forms without changing the technical spirit or essential features. Therefore, the embodiments described above should be understood in all respects as illustrative and not restrictive.

DESCRIPTION OF SYMBOLS

| 100, 1000, 1500, 1600: SAW resonators | |
|---|---|
| 110: Substrate | 120, 125: bus bar |
| 130, 135: IDT electrode | 140, 145: Mass addition film |
| 150, 155: Dummy electrode | 1200, 1300: Reflector |

What is claimed is:

1. A Surface Acoustic Wave (SAW) filter with a mass addition film formed on a plurality of electrodes, the SAW filter comprising:
a substrate on which a support substrate, an energy confinement layer, and a piezoelectric layer are sequentially stacked;
first and second bus bars extended in a first direction on the substrate and spaced apart from each other in a second direction perpendicular to the first direction;
a plurality of IDT electrodes alternately extended from the first and second bus bars in the second direction and spaced apart from each other in the first direction;
a gap formed in a space between an end of the IDT electrode extended from the first bus bar and the second bus bar, or between an end of the IDT electrode extended from the second bus bar and the first bus bar; and
a mass addition film extended in the first direction to cover a top surface of the plurality of IDT electrodes, wherein
when a width of the gap is G, a width in the first direction of a portion where the end of the IDT electrode is formed in the gap due to an alignment error is a, and a thickness of the mass addition film on the IDT electrode is t, (a/G)/t^{1/2}≤0.08 is satisfied.

2. The SAW filter according to claim 1, wherein a density of the mass addition film is 5 g/cm³ or less.

3. The SAW filter according to claim 1, further comprising a first dummy electrode extended from the second bus bar to face the end of the IDT electrode extended from the first bus bar, and a second dummy electrode extended from the first bus bar to face the end of the IDT electrode extended from the second bus bar, wherein the gap is formed in a space between one end of the IDT electrode extended from the first bus bar and the first dummy electrode and in a space between one end of the IDT electrode extended from the second bus bar and the second dummy electrode.

4. The SAW filter according to claim 1, wherein the mass addition film includes at least one among SiO₂, Ta₂O₅, and Al₂O₃.

5. The SAW filter according to claim 1, wherein the mass addition film is extended across the plurality of IDT electrodes in one body to completely fill areas between the plurality of IDT electrodes.

6. The SAW filter according to claim 1, wherein the mass addition film crosses the plurality of IDT electrodes and does not cover a top surface of the substrate exposed between the plurality of IDT electrodes.

7. The SAW filter according to claim 6, wherein a width of a bottom surface of the mass addition film matches a width of the top surface of the IDT electrode covered by the mass addition film.

8. A Surface Acoustic Wave (SAW) filter with a mass addition film formed on a plurality of electrodes, the SAW filter comprising:
a substrate on which a support substrate, an energy confinement layer, and a piezoelectric layer are sequentially stacked;
first and second bus bars extended in a first direction on the substrate and spaced apart from each other in a second direction perpendicular to the first direction;
a plurality of IDT electrodes alternately extended from the first and second bus bars in the second direction and spaced apart from each other in the first direction; and
a mass addition film extended in the first direction to cover a top surface of the plurality of IDT electrodes and a top surface of the substrate exposed between the plurality of IDT electrodes, wherein
a thickness of the mass addition film on the top surface of the substrate and a thickness of the mass addition film on the top surface of the plurality of IDT electrodes are different from each other.

9. The SAW filter according to claim 8, wherein the mass addition film is extended in the first direction to cover one ends of the plurality of IDT electrodes.

10. The SAW filter according to claim 9, wherein the plurality of IDT electrodes includes:
a plurality of first IDT electrodes extended from the first bus bar in the second direction and spaced apart from each other in the first direction; and
a plurality of second IDT electrodes extended from the second bus bar in the second direction, spaced apart from each other in the first direction, and arranged alternately together with the plurality of first IDT electrodes, wherein
the mass addition film includes
a first mass addition film covering one ends of the plurality of first IDTs, and
a second mass addition film covering one ends of the plurality of second IDTs.

11. The SAW filter according to claim 8, wherein the mass addition film includes at least one among SiO₂, Ta₂O₅, and Al₂O₃.

12. The SAW filter according to claim 8, wherein the thickness of the mass addition film on the top surface of the plurality of IDT electrodes is greater than the thickness of the mass addition film on the top surface of the substrate.

13. The SAW filter according to claim 8, wherein the mass addition film is extended across the plurality of IDT electrodes in one body to completely fill areas between the plurality of IDT electrodes.
